(19) United States
(12) Patent Application Publication
(10) Pub. No.: US 2023/0107506 A1
(43) Pub. Date: Apr. 6, 2023

(54) COHERENT HIGH SPEED OPTICAL VALVE

(71) Applicant: California Institute of Technology, Pasadena, CA (US)

(72) Inventors: Junyi Shan, Pasadena, CA (US); Mengxing Ye, Santa Barbara, CA (US); Leon Balents, Santa Barbara, CA (US); David Hsieh, San Marino, CA (US)

(73) Assignee: California Institute of Technology, Pasadena, CA (US)

(21) Appl. No.: 17/940,661

(22) Filed: Sep. 8, 2022

Related U.S. Application Data
(60) Provisional application No. 63/241,674, filed on Sep. 8, 2021.

(51) Int. Cl. G01R 29/08; G02F 1/00

(52) U.S. Cl. CPC G01R 29/0885; G02F 1/0081

(57) ABSTRACT

A control circuit for controlling a timing, a pulse length, a valve electric field having the certain magnitude, and a pulse envelope of the valve electric field, so as to coherently control a response of a region of an insulator to a probe electric field, the response controlled with a temporal resolution equal to the pulse length and matching the pulse envelope.

### CROSS REFERENCE TO RELATED APPLICATIONS

This application claims the benefit under 35 U.S.C. Section 119(e) of the following co-pending and commonly-assigned US Provisional Pat. Application Serial No. 63/241,674 filed Sep. 8, 2021, by David Hsieh, Junyi Shan, Leon Balents, and Mengxing Ye, entitled “Coherent High Speed Optical Valve,” Client Ref. CIT 8697, which application is incorporated by reference herein.

### STATEMENT REGARDING FEDERALLY SPONSORED RESEARCH AND DEVELOPMENT

This invention was made with government support under Grant No. W911NF-16-1-0361 awarded by the Army and under Grant No. PHY1733907 awarded by the National Science Foundation. The government has certain rights in the invention.

### BACKGROUND OF THE INVENTION

### 1. Field of the Invention

The present invention relates to optical valves and methods of making the same.

### 2. Description of the Related Art

(Note: This application references a number of different publications as indicated throughout the specification by one or more reference numbers as superscripts, e.g., ^{x}. A list of these different publications ordered according to these reference numbers can be found below in the section entitled “References.” Each of these publications is incorporated by reference herein.)

Strong periodic driving with light offers the potential to coherently manipulate the properties of quantum materials on ultrafast timescales. Recently, strategies have emerged to drastically alter electronic and magnetic properties by optically inducing non-trivial band topologies¹⁻⁶, emergent spin interactions ⁷⁻¹¹ and even superconductivity ¹². However, the prospects and methods of coherently engineering optical properties on demand are far less understood.¹³

In many applications, the optical response of a material (e.g. transmission, absorption, index of refraction) needs to be altered at high speeds. For example, in a photonic computing circuit, the faster an optical logic gate can switch, the higher the information processing speed. Since the optical properties of a material are set by its electronic band structure, it is important to develop ways to tune electronic band structures at high speeds. Electro-optic effects and opto-mechanical effects are two of the primary pathways to achieve this and are used in commercial devices such as Pockel’s cells and acousto-optical modulators. However, these approaches are limited to MHz to GHz speeds. An alternative approach is the optical valve, or optical transistor - a device whose optical properties can be tuned by a second light source. Currently, optical valves are realized using materials that exhibit large changes in optical properties upon being heated by light (e.g. found in thermochromic smart glass), or with ensembles of atoms or atom-like objects confined in a cavity architectures whose optical properties change under irradiation. However, these schemes are typically limited to GHz speeds and only work for specific wavelengths of light. What is needed are improved methods of coherently controlling light. The present disclosure satisfies this need.

### SUMMARY OF THE INVENTION

The present disclosure reports on a fundamentally new system for realizing an optical valve, which can be made using any electrically insulating crystal. Working embodiments described herein demonstrate significant changes in the optical properties (including, but not limited to, bandgap and nonlinear response) achieved by optically pumping an insulator at an optical frequency that is smaller than the bandgap of the insulator, and smaller than any in-gap excitation.

In one example, we demonstrate coherent control and giant modulation of optical nonlinearity in a van der Waals layered magnetic insulator (manganese phosphorus trisulfide MnPS₃). By driving far off-resonance from the lowest on-site manganese d-d transition, we observe a coherent on-off switching of its optical second harmonic generation efficiency on the timescale of 100 femtoseconds with no measurable dissipation. At driving electric fields of the order of 10⁹ volts per metre, the on-off ratio exceeds 10 , which is limited only by the sample damage threshold. Floquet theory calculations¹⁴ based on a single-ion model of MnPS₃ are able to reproduce the measured driving field amplitude and polarization dependence of the effect. This demonstration illustrates our approach can be applied to a broad range of insulating materials and can lead to dynamically designed nonlinear optical elements.

Devices and methods according to embodiments described herein include, but are not limited to, the following.
1. An optical valve, comprising:
   an insulator comprising:
      a first state and a second state separated in energy by a bandgap and
   coupled by a first dipole allowed transition; and
      a nonlinear susceptibility associated with the first dipole allowed transition;
   a source of a first (e.g., valving) electric field coupled to a region of the insulator, the valve electric field comprising:
      a first frequency corresponding to a photon energy smaller than the bandgap and any in gap energy corresponding to a second dipole allowed transition within the bandgap; and
      a certain magnitude selected for driving a virtual transition between the first state and the second state under Floquet conditions that increase the bandgap by an amount proportional to a square of the magnitude; and
   a control circuit controlling a timing, a pulse length, the magnitude and a pulse envelope of the valve electric field so as to coherently control a response of the region of the insulator to a second (e.g. probe) electric field, the response controlled with a temporal resolution equal to the pulse length and matching the pulse envelope.
2. The optical valve of example 1, wherein the valve electric field having the certain magnitude dresses the states with Floquet sidebands characterized by the first state and the second state gaining a mixing factor cosα wherein α is proportional to the magnitude.
3. The optical valve of example 1, wherein the probe electric field has a second frequency tuned for absorption by the bandgap prior to application of the valve electric field and the control circuit controls a transparency of the region of insulator for the probe electric field by modulating the bandgap.
4. The optical valve of example 1, wherein the control circuit controls a nonlinear response of the region of the insulator to the probe electric field, wherein the nonlinear response is mediated by the nonlinear susceptibility being switched on or off by the valve electric field.
5. The optical valve of example 4, wherein the probe electric field has a second frequency and the control circuit controls a detuning of the second frequency to either side of the first dipole allowed transition so as to enhance or suppress the nonlinear response.
6. An optical rectifier or high harmonic generator comprising the optical valve of example 1, wherein the control circuit controls optical rectification or generation of higher harmonics of the probe electric field via the valve electric field.
7. A cavity comprising the insulator of example 1, “wherein the cavity reduces the magnitude of the valve electric field required to modify the transparency for the electromagnetic radiation comprising the second electric field.
8. An optical transistor comprising the optical valve of example 1, wherein the valve electric field modulates an optical response of the region to the probe electric field.
9. The optical valve of example 1, wherein the insulator comprises a two-dimensional van der Waals layered magnetic insulator or a 2D exfoliable material.
10. The optical valve of example 9, wherein the first state is a spin state comprising A_{1g} symmetry and the second state has charge transfer character.
11. The optical valve of example 1, wherein the insulator comprises ions disposed in two dimensional layers of a honeycomb lattice.
12. The optical valve of example 11, wherein the ions each have spin magnetic moment moments adopting a Neel antiferromagnetic (AFM) arrangement that breaks the inversion symmetry of the honeycomb lattice, allowing a second-order optical nonlinearity of the first dipole allowed transition.
13. The optical valve of example 1, wherein the insulator comprises a magnetic insulator comprising manganese phosphorus trisulfide.
14. The optical valve of example 1, wherein the pulse length is 500 femtoseconds or less.
15. A device, comprising:
   a control circuit for controlling a timing, a pulse length, a first (e.g., valve) electric field having the certain magnitude, and a pulse envelope of the valve electric field, so as to coherently control a response of a region of an insulator to a second (e.g,. probe) electric field, the response controlled with a temporal resolution equal to the pulse length and matching the pulse envelope.
16. The device of example 15, wherein the control circuit controls the magnitude so as to dress a first state and a second state of the insulator with Floquet sidebands characterized by the first state and the second state gaining a mixing factor cosα wherein α is proportional to the magnitude.
17. The device of example 15, wherein the control circuit controls a transparency of the region of insulator for the probe electric field by modulating a bandgap of the insulator.
18. The device of example 15, wherein the control circuit controls a nonlinear response of the region of the insulator to the probe electric field by gating or switching the valve electric field on or off.
19. The device of claim 15, wherein the control circuit controls a detuning of a second frequency of the probe electric field to either side of the first dipole allowed transition between the first state and the second state so as to enhance or suppress a nonlinear response of the insulator to the probe electric field.
20. A method of making an optical valve, comprising:
   providing an insulator comprising:
      a first state and a second state separated in energy by a bandgap and
   coupled by a first dipole allowed transition; and
      a nonlinear susceptibility associated with the first the dipole allowed transition;
   coupling a first source of a valve electric field to a region of the insulator, the valve electric field comprising:
      a first frequency corresponding to a photon energy smaller than the bandgap and any in gap energy corresponding to a second dipole allowed transition within the bandgap; and
      a magnitude selected for driving a virtual transition between the first state and the second state under Floquet conditions that increase the bandgap by an amount proportional to a square of the magnitude; and
   coupling a control circuit to the first source and a second source of a probe electric field, the control circuit controlling a timing, a pulse length, the valve electric field having the certain magnitude, and a pulse envelope of the valve electric field so as to coherently control a response of the region of the insulator to the probe electric field, the response controlled with a temporal resolution equal to the pulse length and matching the pulse envelope.
21. The method of example 20 used for making the device of any of the examples 1-19
22. A method of operating an optical valve, comprising:
   interacting a valve electric field with a probe electric field in a region of an insulator comprising:
      a first state and a second state separated in energy by a bandgap and coupled by a first dipole allowed transition; and
      a nonlinear susceptibility associated with the first the dipole allowed transition;
      wherein the valve electric field comprises:
      a first frequency corresponding to a photon energy smaller than the bandgap and any in gap energy corresponding to a second dipole allowed transition within the bandgap; and
      a magnitude selected for driving a virtual transition between the first state and the second state under Floquet conditions that increase the bandgap by an amount proportional to a square of the magnitude; and
   controlling a timing, a pulse length, the valve electric field having the certain magnitude, and a pulse envelope of the valve electric field so as to coherently control a response of the region of the insulator to the probe electric field, the response controlled with a temporal resolution equal to the pulse length and matching the pulse envelope.
23. The method of example 22 used for operating the device of any of the examples 1-19.

### BRIEF DESCRIPTION OF THE DRAWINGS

Referring now to the drawings in which like reference numbers represent corresponding parts throughout:

FIGS. 1A-1D illustrate static SHG from MnPS₃ . FIG. 1A shows the absorption spectrum of MnPS₃ (black curve) and underlying optical transitions (shaded areas) adapted from ref. ²⁸. FIG. 1B left shows states involved in the resonant ED SHG process (red and blue arrows). FIG. 1B right shows orbital and spin configurations of the states. FIG. 1C is a depiction of the experimental geometry and the AFM spin arrangement on the Mn sublattice. The probe beam (red) is focused obliquely onto the sample and the reflected SHG beam (blue) is measured as a function of the scattering plane angle φ. Both incident and reflected beams are linearly polarized in the scattering plane. The driving beam (green) is focused normally onto the sample with linear polarization along θ. The x and y axes correspond to the crystallographic α and b axes. FIG. 1D shows temperature-dependent SHG intensity acquired at φ = 60° (pink lobe in inset) normalized by its value at 10 K. The error bars represent the standard errors of the mean from four independent measurements. A power-law fitting with β = 0.32(2) is overlaid (black curve). The insets show RA SHG patterns above and below T_{N} (green circles) and fits to the single-ion model (black curves).

FIGS. 2A - 2B. Coherent drive-induced state modification. FIG. 2A shows calculated temporal profile of the energy shift and mixing amplitude of the initial (blue) and final (red) states of the ED SHG process owing to a pulsed periodic drive (black curve). We assumed a Gaussian envelope of width 120 fs, a peak driving field

$${E}_{\text{max}}^{\text{pu}} = {10}^{9} V {m}^{- 1}$$

and polarization θ = 90°. The inset shows the higher Floquet sectors (dashed lines) that hybridize with the states in the zeroth Floquet sector (solid lines). FIG. 2B shows the predicted maximum energy shift versus peak driving field calculated using our full Floquet formalism (Floquet), optical Stark shift (OS), Bloch-Siegert shift (BS), and the sum of OS and BS. The inset shows a calculation of the corresponding change in the magnetic contribution to the SHG intensity

FIGS. 3A-3D illustrate driving photon energy dependence of RA SHG transients. FIG. 3A shows time-resolved RA SHG patterns from MnPS₃ measured at 10 K following a pulsed subgap drive with ℏΩ = 0.66 eV and

$${E}_{\text{max}}^{\text{pu}} = {10}^{9} V {m}^{- 1}$$

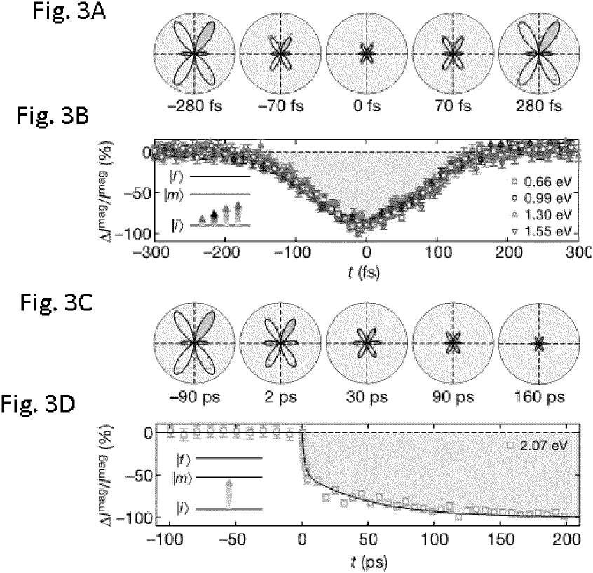

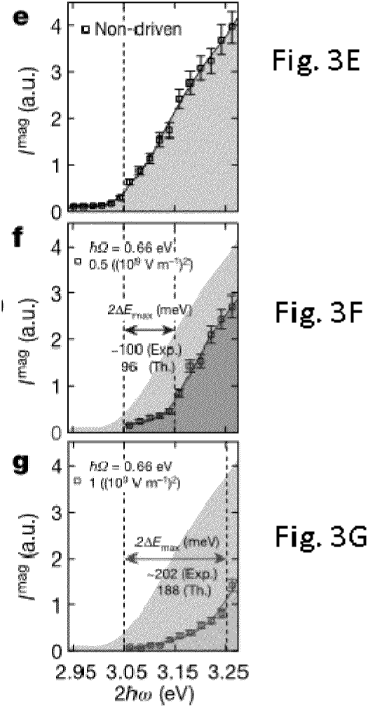

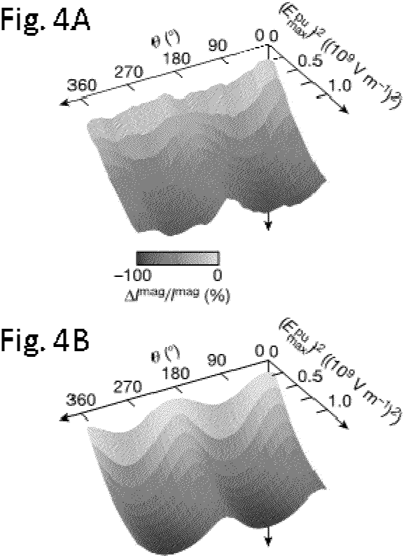

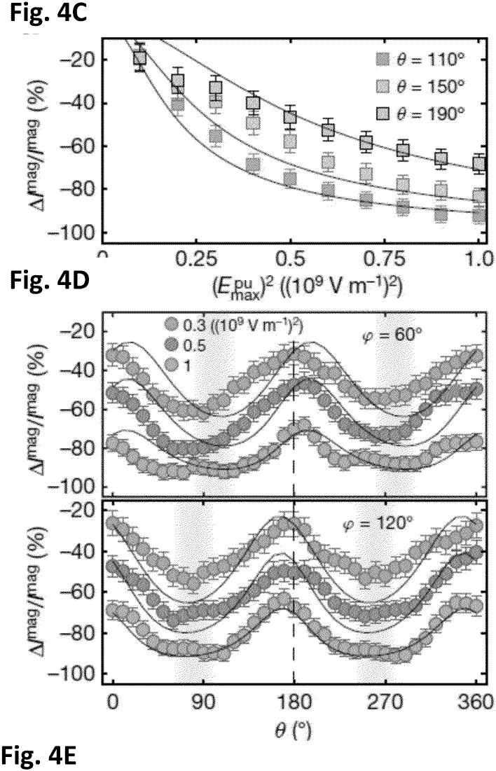

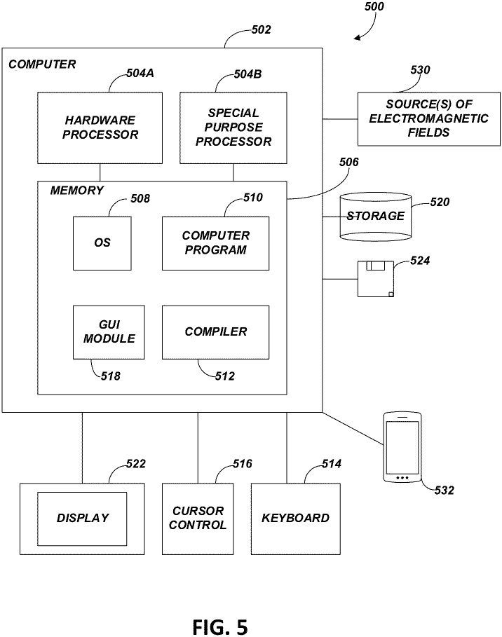

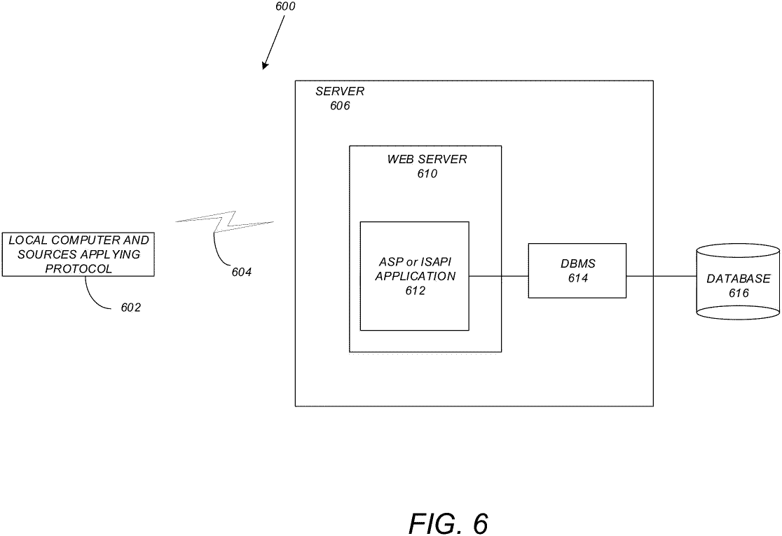

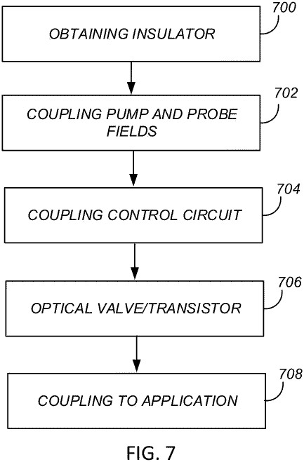

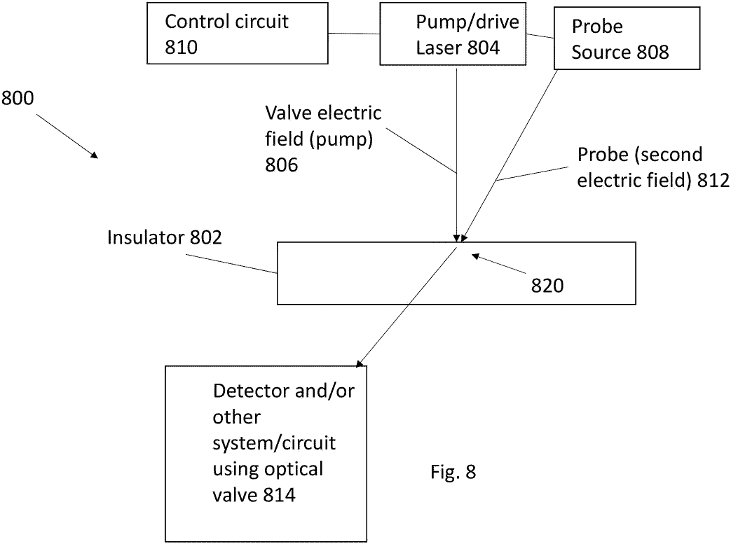

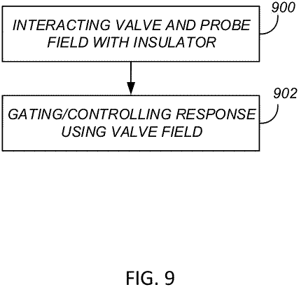

(green circles). The black curves are fits to our Floquet model. FIG. 3B shows ΔI^{mag}/I^{mag} transients measured at φ = 60° (pink lobes in FIG. 3A) for different subgap pump photon energies (inset) and

$${E}_{\text{max}}^{\text{pu}}$$

fixed at 10⁹ V m⁻¹. The red curve shows the theoretically predicted SHG response for a 0.66 - eV drive convolved with the probe-pulse profile. Pump-induced changes in the linear optical response or competing second-order nonlinear processes can be excluded as the cause of SHG suppression (‘Transient fundamental and sum-frequency generation response’ in Methods in ref. 38). FIG. 3C shows Time-resolved RA SHG patterns measured under resonant pumping (ℏΩ = 2.07 eV) conditions (inset) with

$${E}_{\text{max}}^{\text{pu}}$$

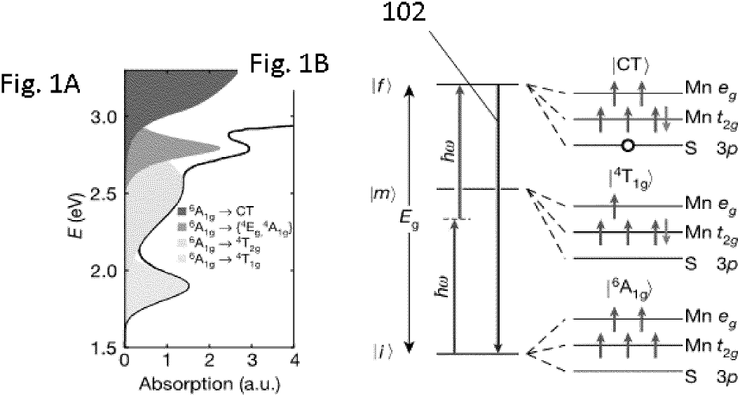

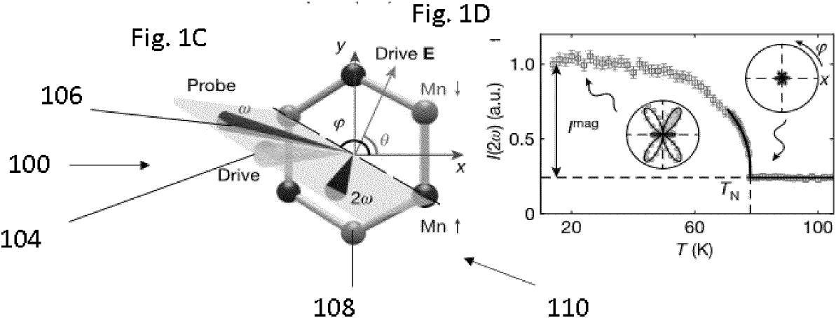

set to 7.5 × 10⁸ V m⁻¹ (green circles). Fits to the static RA patterns (FIG. 1d) at temperatures 10 K, 64 K, 76 K, 77 K and 80 K (left to right) are overlaid for comparison. FIG. 3D shows corresponding ΔI^{mag} /I^{mag} transient for resonant pumping conditions. The black curve is a guide to the eye. FIG. 3E shows nondriven SHG spectrum at 10 K. FIGS. 3F and 3G show transient t = 0 SHG spectra at (Eₘₐₓ)²)² = 0.5(FIG. 3F) and 1(FIG. 3G)(10⁹Vm⁻¹)². Solid curves in FIGS. 3E-3G are guides to the eye and the grey shaded region represents the non-driven spectrum. The vertical dashed lines mark the intensity upturns. Values of the observed (Exp.) and theoretically (Th.) calculated energy shifts are indicated. All error bars represent the standard errors of the mean from four independent measurements.

FIGS. 4A-4D illustrate the driving field amplitude and polarization dependence of SHG of the peak driving field and polarization. FIGS. 4A-4B show two-dimensional maps of the experimentally measured (a) and theoretically predicted (b) value of ΔI^{mag}/I^{mag} at time zero as a function of the peak driving field and polarization. c, One-dimensional cuts through the experimental map (symbols) and theoretical map (black lines) along the field axis at selected θ values. FIG. 4C shows one-dimensional cuts through the experimental map (symbols) and theoretical map (black lines) along the field axis at selected θ values. FIGS. 4D-4E show one-dimensional cuts along the θ axis at selected field strengths for φ = 60° (FIG. 4D) and φ = 120°(FIG. 4E). The positions marked by the faint vertical red bars indicate where the largest ΔI^{mag} /I^{mag} is predicted. The slight horizontal offset between the φ = 60° and φ = 120° curves arises due to a degeneracy of the final state (Supplementary Section 2 in ref. 38), not Rabi frequency anisotropy. All error bars represent the standard errors of the mean from four independent measurements.

FIG. 5 illustrates a hardware environment for implementing one or more embodiments of the present invention.

FIG. 6 illustrates a network environment for implementing one or more embodiments of the present invention.

FIG. 7 illustrates a method of making a device according to one or more embodiments described herein.

FIG. 8 illustrates a device according to one or more embodiments described herein.

FIG. 9 is a flowchart illustrating a method of operating a device according to embodiments described herein.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

### Technical Description

The present disclosure demonstrates the use of Floquet engineering as a non-thermal and broadly applicable strategy to modulate nonlinearity on ultrashort timescales, limited only by the drive pulse duration. Appreciable tuning requires strong driving (pump) electric fields E^{pu} characterized by a Floquet parameter

$$ε ≡ \frac{e a {E}^{p u}}{ℏ Ω}$$

of order unity, where e is the electron charge, α is the atomic spacing, ℏ is the reduced Planck’s constant and Ω is the driving frequency. For a typical solid with α ≈ 3 Å, the requisite field is of the order of 10⁹ V m⁻¹ at optical or near-infrared frequencies, making runaway heating a major obstacle to experimentally realizing Floquet engineering. To mitigate this effect, embodiments described herein drive electrical insulators below their bandgap.

In typical examples, Floquet engineering can be used to modify the bandgap of a material. When the bandgap of a material changes, the wavelength range over which the material is transparent and absorbing changes. In one embodiment, a material that is naturally opaque to 400 nm light becomes transparent to that wavelength upon pumping at a wavelength above 600 nm. However, a variety of properties can be modulated using Floquet engineering, as illustrated in the following examples.

### 1. First Example MnPS₃

The layered honeycomb lattice magnetic insulator manganese phosphorus trisulfide (MnPS₃) is an ideal demonstration platform for the following reasons. First, it exhibits a large direct bandgap E_{g} = 3.1 eV in the visible region ²⁴. Second, the Mn²⁺ moments adopt a Neel antiferromagnetic (AFM) arrangement that breaks the inversion symmetry of its underlying lattice, allowing a finite second-order optical nonlinearity in the electric dipole (ED) channel. This has recently been detected by optical second harmonic generation (SHG) measurements with an SHG photon energy resonant with E_{g}ref. ²⁵). Third, the relatively low AFM ordering temperature (T_{N} = 78 K) allows thermal- versus non-thermal-induced effects to be readily distinguished. Fourth, the timescale for spin dynamics, which may be induced by light directly via magneto-optical effects or indirectly via magneto-elastic coupling ²⁶, is limited to around 5 ps based on the magnetic exchange interaction strength ²⁷. Therefore, any dynamics occurring on the timescale of a femtosecond driving pulse can be confined to the charge sector. Lastly, as the Mn 3d electrons are highly localized, the optical response and transport properties of MnPS₃ are well captured within a single ion picture ²⁸, which enables an analytical derivation of Floquet engineering effects from a microscopic model.

### a. Static SHG from MnPS₃

A single-ion model was developed to understand the AFM-order-induced static SHG from MnPS₃. Owing to the absence of inversion symmetry, this response is dominated by a bulk ED process of the form

$${P}_{i} ( 2 ω ) = {χ}_{i j k}^{\text{ED}} {E}_{j}^{\text{pr}} ( ω ) {E}_{k}^{\text{pr}} ( ω ) ,$$

where the second-order susceptibility tensor

$${χ}_{i j k}^{\text{ED}}$$

governs the relationship between the incident (probe) electric field

$${E}_{i}^{\text{pr}}$$

(w) at frequency ω and the polarization induced at twice the incident probing frequency Pᵢ(2w), and the indices i, j, k run over the x, y and z coordinates. As shown in the experiments, we exclusively detect the time-reversal odd (c type) ²⁹ component of

$${χ}_{i j k '}^{\text{ED}}$$

which couples linearly to the AFM order parameter. For a near resonant process where 2ℏω ≈ E_{g}, the quantum mechanical expression for

$${χ}_{i j k}^{\text{ED} \left(\text{c}\right)}$$

is given by ³⁰

$${χ}_{i j k}^{\text{ED} \left(c\right)} ∝ \sum \frac{\left〈i \left|{r}_{i}\right| f\right〉 \left〈f \left|{r}_{j}\right| m\right〉 \left〈m \left|{r}_{k}\right| i\right〉}{\left({E}_{\text{f}} - {E}_{\text{i}} - 2 ℏ ω - i {γ}_{\text{f}}\right) \left({E}_{\text{m}} {E}_{\text{i}} - ℏ ω\right)} + \left(j ↔ k\right)$$

where the sum is performed over Mn²⁺ ions in a unit cell, |i〉, |m〉 and |f〉 are the ground, intermediate and final states of the SHG process, Eᵢ, Eₘ and E_{f} denote their respective energies, r is the position operator, and γ_{f} is a phenomenological decay rate of the final state (‘Determination of E_{g} and γ_{f}’ in Methods). In the presence of an octahedral crystal field imposed by the sulfur ions, the five-fold degenerate Mn 3d orbitals split into a low-energy t_{2g} triplet and a high-energy e_{g} doublet. The ground state is a high-spin (S = 5/2) state characterized by a

$${t}_{2 g}^{3} {e}_{g}^{2}$$

orbital configuration with ⁶A₁_{g} symmetry. According to previous optical absorption measurements (FIG. 1A )²⁸, the intermediate state has predominantly

$${}^{4} {T}_{1 g} \left({t}_{2 g}^{4} {e}_{g}^{1}\right)$$

character (S = 3/2) and the final state has predominantly S 3p → Mn 3d charge transfer (CT) character (S = 5/2). The |f〉 state has opposite parity to the |i〉 and |m〉 states.

By introducing spin-orbit coupling λ and a trigonal distortion of the crystal field η as perturbations to the states described above ³¹, optical transitions |i〉 → |m〉 and |m〉 → |f〉 become ED allowed (FIG. 1B). Upon coherently summing the single-ion contributions from two Mn²⁺ sites in the unit cell, one obtains

$${χ}_{i j k}^{\text{ED} \left(\text{c}\right)} ∝ {β}_{i j k} {λ}^{2} η \left({S}_{z , 1} - {S}_{z , 2}\right)$$

, where (S_{z,1} - S_{z,2}) is the staggered moment perpendicular to the honeycomb plane. The coefficient βᵢⱼₖ encodes the symmetry of the underlying crystal through the matrix elements in equation (1). To capture the loss of three-fold rotational symmetry owing to coupling between adjacent honeycomb layers displaced along x, we assign unequal weight to the dipole matrix elements along x and y.

To verify this static SHG model, rotational anisotropy (RA) measurements ³² were performed using near-resonant probe light (ℏω = 1.55 eV). The beam was focused obliquely onto a bulk MnPS₃ single crystal and specular reflected SHG light was collected as a function of the scattering plane angle φ (FIG. 1C). Above T_{N}, we observe a weak temperature-independent SHG signal arising from time-reversal even (i type) higher multipole bulk crystallographic SHG processes (FIG. 1D), consistent with the report in ²⁵. Below T_{N}, the intensity, collected at φ = 60°, undergoes a steep upturn that can be fitted to a power law

$${X}_{i j k}^{E D \left(\text{c}\right)} ∝ {( {T}_{N} - T )}^{β}$$

with β = 0.32. This is in excellent agreement with the critical exponent of the AFM order parameter (β = 0.32) obtained from neutron diffraction ³³ (‘Linear coupling of

$${χ}_{i j k}^{\text{ED} \left(\text{c}\right)}$$

to the AFM order parameter’ in Methods), confirming its linear coupling to

$${χ}_{i j k}^{\text{ED} \left(\text{c}\right)}$$

as predicted in our model. The enhanced anisotropy of the RA pattern below T_{N} arises from interlayer coupling and is fully captured in our model through the βᵢⱼₖ coefficient (FIG. 1D, inset).

### c. Dynamical Floquet Model

The effect of electric field oscillating at a subgap frequency on the electronic spectrum of MnPS₃ can be studied within our single-ion model. As this drive mainly hybridizes |i〉 and |f〉 owing to their opposite parity and equal spin, the three-level problem can be simplified to a two-level one, described by the following time-dependent Hamiltonian

$$H \left(t\right) = {H}_{0} + e \text{r} ⋅ {\text{E}}^{\text{pu}} cos Ω t$$

where H₀ is the unperturbed 2 × 2 Hamiltonian, r is the position operator and t is time. By diagonalizing the time-independent Floquet Hamiltonian ³ (H_{F})ₘₙ =

$$\frac{1}{2 π / Ω} {\int }_{0}^{2 π / Ω} {\text{e}}^{\text{i} Ω t ( m - n )} H ( t ) - n ℏ Ω {δ}_{m n}$$

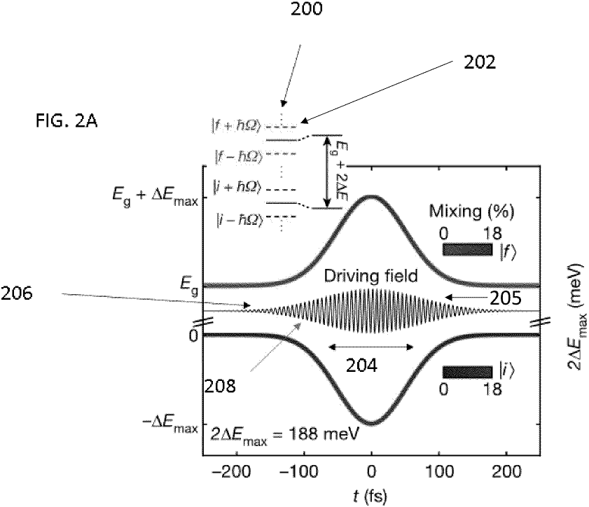

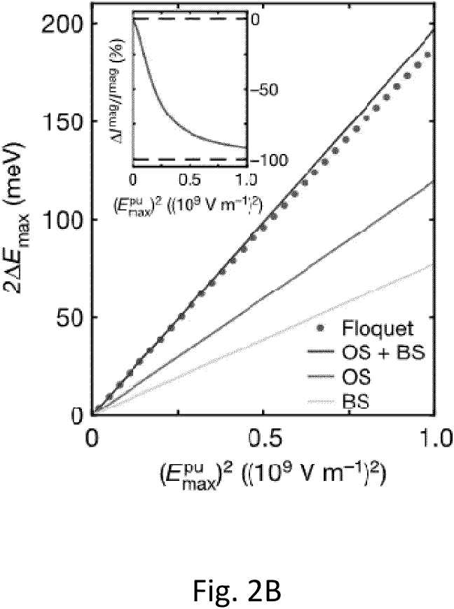

truncated at the ±3 rd Floquet sector (FIG. 2A, inset), where m and n denote the index of the Hilbert space basis and δ is the Kronecker delta, we obtain the pump field dressed initial and final states |i′〉 and |f′〉

$$\left|{i}^{′}\right〉 = {\text{e}}^{- \text{i} \left({E}_{\text{i}} - Δ E\right) t / ℏ} \left(cos α \left|i\right〉 + sin α {\text{e}}^{\text{i} φ \left(t\right)} \left|f\right〉\right)$$

$$\left|{f}^{′}\right〉 = {\text{e}}^{- \text{i} \left({E}_{\text{f}} + Δ E\right) t / ℏ} \left(- sin α {\text{e}}^{- \text{i} φ \left(t\right)} \left|i\right〉 + cos α \left|f\right〉\right)$$

where ΔE is the energy shift and the hybridization is parameterized by a mixing amplitude sin α and phase ϕ(t), which all depend on E^{pu} (Supplementary Section 2 in ref. 38). In this model, periodic driving serves to modify the single-ion states involved in an SHG scattering process. This is distinct from Floquet engineering proposals where periodic driving is used to renormalize the low-energy Hamiltonian of a many-body system ⁷ . For a Gaussian pulsed drive, the calculations show that in the adiabatic limit where the pulse width far exceeds Ω-1, both the bandgap and hybridization undergo a temporal increase that follows the pulse envelope (FIG. 2A), attaining maximum values at the peak pump field

$${E}_{\text{max}}^{\text{pu}} .$$

The maximal mixing amplitude scales linearly with

$${E}_{\text{max}}^{\text{pu}}$$

as expected from a perturbative treatment, whereas the maximal bandgap increase (2ΔE) scales like the square of

$${E}_{\text{max}}^{\text{pu}} .$$

Although this quadratic dependence is reminiscent of the optical Stark effect ^{34,35}, the Floquet treatment goes beyond the rotating wave approximation by including both optical Stark and Bloch-Siegert shifts ³⁶ (FIG. 2B) as well as the influence of higher Floquet sectors, predicting 2ΔEₘₐₓ as large as 188 meV for

$${E}_{\text{max}}^{\text{pu}} = {10}^{9} V {m}^{- 1}$$

.

Both mixing and bandgap widening, imparted by a coherent modulation of the two-level Hamiltonian composed of |i〉 and |f〉, should suppress the magnitude of

$${χ}_{i j k}^{\text{ED} \left(\text{c}\right)}$$

because the former reduces the amplitude of states in the zeroth Floquet sector-the dominant contribution to

$${χ}_{i j k}^{\text{ED} \left(\text{c}\right)}$$

-by a factor of cos α, whereas the latter shifts the resonance condition away from ℏω = 1.55 eV. The fast-oscillating pump field induces a quasi-static change in the time-averaged value of

$${χ}_{i j k}^{\text{ED} \left(\text{c}\right)}$$

that follows the slower pump-pulse envelope, consistent with a Floquet description. To quantify these effects, we computed the expected change in χ

$${}_{i j k}^{\text{ED} \left(\text{c}\right)}$$

and the resulting modulation of the magnetic contribution to the SHG intensity ƒ^{mag} (FIG. 1D) within our single-ion model using the dressed initial and final states, assuming ℏΩ well below the ⁶ A₁_{g} → ⁴ T₁_{g} transition and E^{pu} parallel to the nearest-neighbour Mn - Mn bond (pump field polarization angle θ = 90° ). As shown in the inset of FIG. 2B, the model predicts an inverse power-law-like dependence of |^{∧}mag on the driving field amplitude, indicating that the suppression is predominantly caused by energy shifts that affect the denominator in equation (1). Remarkably , the model predicts that Floquet engineering can impart a giant suppression exceeding 90% at readily attainable field strengths of the order of 10⁹ V m⁻¹.

### d. Time-Resolved SHG Measurements

To experimentally test our prediction, time-resolved pump-probe RA SHG measurements were performed in the AFM phase of MnPS₃. To minimize dissipation and decoherence, the pump photon energy was tuned below the ⁶ A₁_{g} → ⁴T₁_{g} transition edge near 2 eV to avoid absorption, but above 0.5 eV to suppress the effects of quantum tunnelling between the valence and conduction bands, phonon resonances and photo-assisted inter-site hopping (Supplementary Section 3 in ref. 38) that are more pronounced at lower frequencies. Gaussian pump- and probe-pulse envelopes of 120 fs and 80 fs duration were used, respectively, satisfying the adiabatic condition. FIG. 3A shows instantaneous RA patterns at selected time delays measured using θ = 90° and

$${E}_{\text{max}}^{\text{pu}} = {10}^{9} V {m}^{- 1}$$

. The magnitude of the RA patterns is drastically reduced during pumping and can be fit by simply decreasing all

$${X}_{i j k}^{\text{ED} \left(c\right)}$$

elements uniformly. The temporal evolution of the RA patterns is completely symmetric about time t = 0-the instant when pump and probe pulses are exactly overlapped-and the transient SHG intensity change

ΔI^{mag}/I^{mag} exhibits a temporal profile that matches the theoretically predicted SHG profile convolved with the probe pulse (FIG. 3B). These data indicate a coherent and uniform modulation of the 2′/m magnetic point group allowed

$${χ}_{i j k}^{\text{ED} \left(c\right)}$$

elements with no measurable dissipation (‘Time-resolved SHG data at 70 K and 90 K’ in Methods), in accordance with a Floquet engineering process. The maximal suppression of I^{mag} reaches around 90% and is unchanged upon sweeping ℏΩ from 0.66 eV to 1.55 eV, in full agreement with our theoretical model (Supplementary Section 2 in ref. 38).

In contrast, measurements performed with ℏΩ tuned near

the ⁶A₁_{g} → ⁴T₁_{g}absorption peak reveal dynamics that are strongly asymmetric about t = 0. Following an initial fast coherent reduction of I^{mag} , there is a slow exponential decay to 100% suppression, where it remains for more than 500 ps (FIG. 3D). The decay and plateau are consistent with an incoherent quasi-thermal melting of the AFM order via heat transfer from the optically excited electronic subsystem to the spin subsystem, followed by a very slow cooling of the pumped region through diffusion (‘Proof of the heating picture for ℏΩ = 2.07 eV drive’ in Methods in ref. 38). This interpretation is further corroborated by instantaneous RA data acquired within the exponential decay time window, which directly map onto our temperature-dependent RA data (FIG. 3C).

To directly confirm the predicted bandgap widening effect (FIGS. 2A 2B ), transient SHG spectroscopy measurements were performed with ℏΩ = 0.66 eV. The equilibrium SHG spectrum exhibits a steep intensity upturn near the band edge of MnPS₃ (FIG. 3E), closely following the linear optical absorption spectrum ²⁴. This is expected as the absorption spectrum is featureless over the measured range of incident (fundamental) photon energies. Upon driving, the band edge feature instantaneously shifts to higher energy, which is opposite to the typical response of electronic gaps to photoexcitation. The size of the positive shift at t = 0 increases monotonically with

$${E}_{\text{max}}^{\text{pu}}$$

and agrees reasonably well with our theoretically predicted values (FIGS. 3F, 3G), further supporting the Floquet engineering interpretation.

As both the bandgap widening and level mixing are dependent on the Rabi frequency 〈f|er • E^{pu}/ℏ|i〉, we expect the magnitude of SHG modulation to be tunable by both the electric field amplitude and polarization of the pump pulse. To study this relationship, a comprehensive experimental mapping of ΔI/I^{mag}(t = 0) was performed as a function of both

$${E}_{\text{max}}^{\text{pu}}$$

and θ using ℏΩ = 0.66 eV (FIG. 4A). A comparison with our model calculation performed over the same parameter space (FIG. 4B), using the same weighting of dipole matrix elements along x and y as in our static model to account for inter-layer coupling, shows excellent agreement in overall trend. More detailed comparisons can be drawn by taking different one-dimensional cuts through our dataset. For a fixed θ, ΔI^{mag}/I^{mag} exhibits an expected inverse power-law-like dependence on the pump field in both experiment and theory (FIG. 4C ), with good agreement on the level of suppression. For a fixed pump field, we observe a sinusoidal dependence of ΔI^{mag}/I^{mag} on θ that is reproduced in our calculations (FIG. 4D). Although the three-fold rotational symmetry of an isolated honeycomb layer forbids an anisotropic Rabi frequency, this is broken in bulk MnPS₃ owing to the layer stacking (FIG. 1D, inset), resulting in a maximum (minimum) Rabi frequency at θ = 90°(0°). The fact that the θ dependence remains largely unchanged upon rotating φ (FIG. 4E ) confirms that the anisotropy is intrinsic to the crystal and is unrelated to the relative polarization of the pump and probe light. The close agreement between our measurements and theoretical calculations, which contain no free parameters, confirms the validity of our single-ion treatment and highlights its dominant role over photo-assisted inter-site hopping effects in our experiments (Supplementary Section 3 in ref. 38).

### Possible Modifications and Variations

The Floquet engineering strategy demonstrated here can be broadly applied to coherently control a variety of nonlinear optical processes including optical rectification and higher harmonic generation. Moreover, both coherent enhancement and suppression of the nonlinear response can in principle be realized by tuning the probe photon energy to either side of an absorption resonance peak. Introducing few-layer exfoliable materials such as MnPS₃ into cavity architectures ³⁷ enables coherently switchable optical, optoelectronic and magnetic devices with reduced external field thresholds.

### Hardware Environment

FIG. 5 is an exemplary hardware and software environment 1500 (referred to as a computer-implemented system and/or computer-implemented method) used to implement one or more embodiments of the invention. The hardware and software environment includes a computer 502 and may include peripherals. Computer 502 may be a user/client computer, server computer, or may be a database computer. The computer 502 comprises a hardware processor 504A and/or a special purpose hardware processor 504B (hereinafter alternatively collectively referred to as processor 504) and a memory 506, such as random access memory (RAM). The computer 502 may be coupled to, and/or integrated with, other devices, including input/output (I/O) devices such as a keyboard 514, a cursor control device 516 (e.g., a mouse) a pointing device, pen and tablet, touch screen, multi-touch device, etc.) and a printer 528. In one or more embodiments, computer 502 may be coupled to, or may comprise, a portable or media viewing/listening device 532. In yet another embodiment, the computer 502 may comprise a multi-touch device, mobile phone, or other internet enabled device executing on various platforms and operating systems.

In one embodiment, the computer 502 operates by the hardware processor 504A performing instructions defined by the computer program 510 under control of an operating system 508. The computer program 510 and/or the operating system 508 may be stored in the memory 506 and may interface with the user and/or other devices to accept input and commands and, based on such input and commands and the instructions defined by the computer program 510 and operating system 508, to provide output and results.

Output/results may be presented on the display 522 or provided to another device for presentation or further processing or action. The image may be provided through a graphical user interface (GUI) module 518. Although the GUI module 518 is depicted as a separate module, the instructions performing the GUI functions can be resident or distributed in the operating system 508, the computer program 510, or implemented with special purpose memory and processors.

Some or all of the operations performed by the computer 502 according to the computer program 510 instructions may be implemented in a special purpose processor 504B. In this embodiment, some or all of the computer program 510 instructions may be implemented via firmware instructions stored in a read only memory (ROM), a programmable read only memory (PROM) or flash memory within the special purpose processor 504B or in memory 506. The special purpose processor 504B may also be hardwired through circuit design to perform some or all of the operations to implement the present invention. Further, the special purpose processor 504B may be a hybrid processor, which includes dedicated circuitry for performing a subset of functions, and other circuits for performing more general functions such as responding to computer program 510 instructions. In one embodiment, the special purpose processor 504B is an application specific integrated circuit (ASIC) or field programmable gate array (FPGA). In other examples, special purpose processor may comprise a graphics processing unit (GPU).

The computer 502 may also implement a compiler 512 that allows an application or computer program 510 written in a programming language such as C, C++, Assembly, SQL, PYTHON, PROLOG, MATLAB, RUBY, RAILS, HASKELL, or other language to be translated into processor 504 readable code. Alternatively, the compiler 512 may be an interpreter that executes instructions/source code directly, translates source code into an intermediate representation that is executed, or that executes stored precompiled code. Such source code may be written in a variety of programming languages such as JAVA, JAVASCRIPT, PERL, BASIC, etc. After completion, the application or computer program 510 accesses and manipulates data accepted from I/O devices and stored in the memory 506 of the computer 502 using the relationships and logic that were generated using the compiler 512.

The computer 502 also optionally comprises an external communication device such as a modem, satellite link, Ethernet card, or other device for accepting input from, and providing output to, other computers 502.

In one embodiment, instructions implementing the operating system 508, the computer program 510, and the compiler 512 are tangibly embodied in a non-transitory computer-readable medium, e.g., data storage device 520, which could include one or more fixed or removable data storage devices, such as a zip drive, floppy disc drive 524, hard drive, CD-ROM drive, tape drive, etc. Further, the operating system 508 and the computer program 510 are comprised of computer program 510 instructions which, when accessed, read and executed by the computer 502, cause the computer 502 to perform the steps necessary to implement and/or use the present invention or to load the program of instructions into a memory 506, thus creating a special purpose data structure causing the computer 502 to operate as a specially programmed computer executing the functions of the control circuit controlling the valve electric field and probe electric field according to the functionalities described herein. Computer program 510 and/or operating instructions may also be tangibly embodied in memory 506 and/or embodied in or coupled to source 530 of the pulses 206 comprising electromagnetic fields (e.g., 530 may comprise sources 804, 808), thereby making a computer program product or article of manufacture according to the invention. As such, the terms “article of manufacture,” “program storage device,” and “computer program product,” as used herein, are intended to encompass a computer program accessible from any computer readable device or media. Computer 500 may comprise or be coupled to 530.

Of course, those skilled in the art will recognize that any combination of the above components, or any number of different components, peripherals, and other devices, may be used with the computer 502.

FIG. 6 schematically illustrates a typical distributed/cloud-based computer system 600 using a network 604 to connect client computers 602 to server computers 606. A typical combination of resources may include a network 604 comprising the Internet, LANs (local area networks), WANs (wide area networks), SNA (systems network architecture) networks, or the like, clients 602 that are personal computers or workstations (as set forth in FIG. 5), and servers 606 that are personal computers, workstations, minicomputers, or mainframes (as set forth in FIG. 5). However, it may be noted that different networks such as a cellular network (e.g., GSM [global system for mobile communications] or otherwise), a satellite based network, or any other type of network may be used to connect clients 602 and servers 606 in accordance with embodiments of the invention.

A network 604 such as the Internet connects clients 602 to server computers 606. Network 604 may utilize ethernet, coaxial cable, wireless communications, radio frequency (RF), etc. to connect and provide the communication between clients 602 and servers 606. Further, in a cloud-based computing system, resources (e.g., storage, processors, applications, memory, infrastructure, etc.) in clients 602 and server computers 606 may be shared by clients 602, server computers 606, and users across one or more networks. Resources may be shared by multiple users and can be dynamically reallocated per demand. In this regard, cloud computing may be referred to as a model for enabling access to a shared pool of configurable computing resources.

Clients 602 may execute a client application or web browser and communicate with server computers 606 executing web servers 610. Such a web browser is typically a program such as MICROSOFT INTERNET EXPLORER/EDGE, MOZILLA FIREFOX, OPERA, APPLE SAFARI, GOOGLE CHROME, etc. Further, the software executing on clients 602 may be downloaded from server computer 606 to client computers 602 and installed as a plug-in or ACTIVEX control of a web browser. Accordingly, clients 602 may utilize ACTIVEX components/component object model (COM) or distributed COM (DCOM) components to provide a user interface on a display of client 602. The web server 610 is typically a program such as MICROSOFT’S INTERNET INFORMATION SERVER.

Web server 610 may host an Active Server Page (ASP) or Internet Server Application Programming Interface (ISAPI) application 612, which may be executing scripts.

Generally, these components 600-616 all comprise logic and/or data that is embodied in/or retrievable from device, medium, signal, or carrier, e.g., a data storage device, a data communications device, a remote computer or device coupled to the computer via a network or via another data communications device, etc. Moreover, this logic and/or data, when read, executed, and/or interpreted, results in the steps necessary to implement and/or use the present invention being performed.

Although the terms “user computer”, “client computer”, and/or “server computer” are referred to herein, it is understood that such computers 602 and 606 may be interchangeable and may further include thin client devices with limited or full processing capabilities, portable devices such as cell phones, notebook computers, pocket computers, multi-touch devices, and/or any other devices with suitable processing, communication, and input/output capability.

Of course, those skilled in the art will recognize that any combination of the above components, or any number of different components, peripherals, and other devices, may be used with computers 602 and 606. Embodiments of the invention are implemented as a software protocol application on a client 602 or server computer 606. Further, as described above, the client 602 or server computer 606 may comprise a thin client device or a portable device that has a multi-touch-based display.

### Process Steps

FIG. 7 is a flowchart illustrating a method of making an optical valve or a system implementing the optical valve (referring also to FIGS. 1A-1D 2A 2B 3A–3G 4A–4E 5–6 and 8).

Block 700 represents obtaining an insulator 100, 802 comprising a first state and a second state separated in energy by a bandgap and coupled by a first dipole allowed transition; and a nonlinear susceptibility associated with the first the dipole allowed transition. The step can comprise defining a input to the insulator (for receiving the probe and pump electromagnetic fields), a gating or channel region for interacting the pump and probe fields, and an output for outputting the probe electromagnetic field. The insulator may be patterned with waveguides and couplers, e.g., a photonic integrated circuit, for inputting and interacting the valve and probe electric fields.

Block 702 represents providing and coupling a source (e.g., a laser 804) of electromagnetic radiation 104 having a pump (valving/valve/driving) electromagnetic/electric field 806 and a source 808 of electromagnetic radiation 106 comprising the second (e.g., probe) electromagnetic field. In one or more examples, the source 808 comprises a laser or a nonlinear medium, e.g., optical parametric amplifier, pumped by valving source 804.

Without being bound by any specific scientific theory, FIG. 3B shows the frequency of the drive electric field does not play a big role in the gating, as long as it is sufficiently detuned from any in-gap transitions. If it is not detuned sufficiently, heating dominates the process (as illustrated in FIG. 3D) and the gating effect will not be seen.

Block 704 represents coupling one or more control circuits 500, 810 to the sources 804, 808 for controlling the output of the sources (e.g., at least one of a timing, amplitude, pulse length 204 or frequency of the pump and/or probe electromagnetic fields or pulses 206 comprising the fields). ). In one or more examples, the sources of the pulses of the fields (e.g., the laser(s)) comprise the one or more control circuits e.g., as an embedded system or processor, e.g., so as to form smart or programmable sources. The one or more circuits may be in central controller or distributed among the sources. In one or more examples, the control circuit comprises an arbitrary waveform generator (AWG) outputting the timing control signals to the laser sources. In one or more examples, the AWG comprises an FPGA connected to a digital to analog converter.

In one or more examples, the one or more control circuits comprise a computer comprising or coupled to one or more processors; one or more memories; and one or more programs stored in the one or more memories, wherein the one or more programs executed by the one or more processors control the implementation of the coherent control described herein using the valving electric field.

Block 706 represents the end result, a device 800 or system comprising or implementing an optical valve or optical transistor, as illustrated in FIG. 8.

Block 708 represents coupling the device (e.g., optical valve/transistor) in or to an application or system 814 comprising, for example, a circuit (e.g., photonic integrated circuit), a modulator, a cavity, a computer, a detector, or a rectifier. The probe electric field may be transmitted through system and carry signals or other information used by the system. The device may modulate the signals according to the configuration or requirements of the system.

Devices or systems according to embodiments described herein include, but are not limited to, the following.
1. FIGS. 1A-1D, FIG. 2A, and FIG. 8 illustrate an example of an optical valve 800, comprising:
an insulator 802, 100 comprising:
a first state |i> and a second state |f>separated in energy by a bandgap Eg of the insulator 802 and coupled by a first dipole allowed transition 102; and
a nonlinear susceptibility
$${χ}_{i j k}^{\text{ED}}$$
associated with the first dipole allowed transition 102;
a source (e.g., laser 804) of a valve (or valving, or gating or first) electric field 806, 106 coupled to a region 820 (e.g., gating or channel region) of the insulator, the valve electric field comprising:
   a first frequency corresponding to a photon energy smaller than the bandgap Eg and any in gap energy corresponding to a second dipole allowed transition within the bandgap; and
   a (e.g., a certain, predetermined, or particular) magnitude selected for driving a virtual transition 200 between the first state and the second state under Floquet conditions that increase the bandgap Eg by an amount proportional to a square of the magnitude; and
a computer 500 or control circuit 500, 810 controlling a timing, a pulse length 204, the magnitude 205 and a pulse envelope 208 of the valve electric field 806 so as to coherently control a response of the region 820 of the insulator 802 to a probe or second electric field 812, 104 the response controlled with a temporal resolution equal to the pulse length 204 and matching the pulse envelope 208.
2. The optical valve of example 1, wherein the valve electric field 806 having the certain magnitude 205 dresses the states with Floquet sidebands 202 characterized by the first state |i> and the second state |f> gaining a mixing factor cosα wherein α is proportional to the magnitude.
3. The optical valve of example 1 or 2, wherein the probe electric field 812 has a second frequency tuned for absorption by the bandgap Eg prior to application of the valving electric field 806 and the control circuit 500 controls a transparency of the region 820 of insulator 802 for the probe electric field 812 by modulating the bandgap.
4. The optical valve of any of the examples 1-3, wherein the control circuit 500 controls a nonlinear response of the region 820 of the insulator 802 to the probe electric field 812, wherein the nonlinear response is mediated by the nonlinear susceptibility being switched on or off by the valve electric field 806.
5. The optical valve of example 4, wherein the probe electric field 812 has a second frequency and the control circuit 500 controls a detuning of the second frequency to either side of the first dipole allowed transition 102 so as to enhance or suppress the nonlinear response.
6. An optical rectifier 814 or high harmonic generator comprising the optical valve 800 of any of the examples 1-5, wherein the control circuit 500 controls optical rectification or generation of higher harmonics of the probe electric field 812 via the valving electric field 806.
7. A cavity comprising the insulator of any of the examples 1-5, wherein the cavity reduces the magnitude of the valve electric field 806 required to modify the transparency for the electromagnetic radiation comprising the second/probe electric field 812.
8. An optical transistor comprising the optical valve of any of the examples 1-5, wherein the valve electric field 806 modulates an (e.g., optical) response of the region 820 to the probe electric field 812.
9. FIGS. 1A-1D illustrates an example of the optical valve of any of the examples 1-8, wherein the insulator 100 comprises a two- dimensional van der Waals layered magnetic insulator or a 2D exfoliable material.
10. FIGS. 1A-1D illustrates an example of the optical valve of example 9, wherein the first state |i> is a spin state comprising A_{1g} symmetry and the second state |f> has charge transfer character.
11. FIGS. 1A-1D illustrates an example of the optical valve of any of the examples 1-10, wherein the insulator 100 comprises ions 108 disposed in two dimensional layers of a honeycomb lattice 110.
12. FIGS. 1A-1D illustrates an example of the optical valve of example 11, wherein the ions 108 each have spin magnetic moment moments adopting a Neel antiferromagnetic (AFM) arrangement that breaks the inversion symmetry of the honeycomb lattice, allowing a second-order optical nonlinearity of the first dipole allowed transition.
13. FIGS. 1-14 illustrate an example of the optical valve of example 1, wherein the insulator 802 comprises a magnetic insulator comprising manganese phosphorus trisulfide.
14. The optical valve of any of the examples 1-13, wherein the pulse length 204 (FWHM) is 500 femtoseconds or less.
15. A device 800, comprising:
   a control circuit 810 or computer 500 for controlling a timing, a pulse length 204, a valve electric field 806 having the magnitude 205, and a pulse envelope 208 of the valve electric field, so as to coherently control a response of a region 820 of an insulator 802 to a probe electric field 812, the response controlled with a temporal resolution equal to the pulse length 204 and matching the pulse envelope 208.
16. The device of example 15, wherein the control circuit 810 or computer 500 controls the magnitude 205 so as to dress a first state |i> and a second state |f> of the insulator with Floquet sidebands 202 characterized by the first state and the second state gaining a mixing factor cosα wherein α is proportional to the magnitude.
17. The device of example 15 or 16, wherein the control circuit 500 or computer controls a transparency of the region 820 of insulator for the probe electric field 812, 106 by modulating a bandgap Eg of the insulator.
18. The device of any of the examples 15-17 , wherein the control circuit 500 or computer controls a nonlinear response of the region of the insulator 802 to the probe electric field 812 by gating or switching the valve electric field 104, 806 on or off.
19. The device of example 15, wherein the control circuit 500 or computer controls a detuning of a second frequency of the probe electric field 812 to either side of the first dipole allowed transition 102 between the first state |i> and the second state |f> so as to enhance or suppress a nonlinear response of the insulator 802 to the probe electric field.
20. The device of any of the examples, wherein the insulator is patterned with an input, and output, waveguides, and couplers for inputting, outputting and interacting the valving and probe electric fields.
21. FIG. 9 illustrates s method of operating an optical valve, comprising:
   interacting (Block 900) a valving electric field with a probe electric field in a region of an insulator (or gating a response of the insulator to a probe electric field using a valve electric field) comprising:
   a first state and a second state separated in energy by a bandgap and coupled by a first dipole allowed transition; and
   a nonlinear susceptibility associated with the first the dipole allowed transition;
   wherein the valve electric field comprises:
   a first frequency corresponding to a photon energy smaller than the bandgap and any in gap energy corresponding to a second dipole allowed transition within the bandgap; and
   a magnitude selected for driving a virtual transition between the first state and the second state under Floquet conditions that increase the bandgap by an amount proportional to a square of the magnitude; and
   controlling (Block 902) a timing, a pulse length, the valve electric field having the certain magnitude, and a pulse envelope of the valve electric field so as to coherently control a response of the region of the insulator to the probe electric field, the response controlled with a temporal resolution equal to the pulse length and matching the pulse envelope.
22. The device or method of any of the examples 1-120, wherein the insulator comprises a charge transfer insulator.
23. The device or method of any of the examples 1-21, wherein the insulator has the bandgap of around 1 eV or larger.
24. The device or method of any of the examples, wherein the dipole allowed transitions are defined as transitions between states with opposite parities but the same spin quantum number.
25. The device or method of any of the examples 1-23, wherein the valving electric field has the first frequency sufficiently detuned from any in-gap transitions so as to avoid the valving electric field from heating the insulator (see e.g., FIG. 3B), or to prevent any heating caused by the valving electric field from dominating (as illustrated in FIG. 3D) the coherent control modulated by the magnitude of the valving electric field according to the valving/gating effects described herein.
26. The device or method of any of the examples, wherein the control circuit comprises or is coupled to a computer comprising or coupled to one or more processors; one or more memories; and one or more programs stored in the one or more memories, wherein the one or more programs executed by the one or more processors control controlling a timing, a pulse length, the valve electric field having the certain magnitude, and a pulse envelope of the valve electric field.
27. A computer 500 and/or control circuit 810 for controlling a timing of a valve electric field, a pulse length 204 of the first (e.g., valve) electric field 806, a magnitude 205 or amplitude of the first (e.g., valve) electric field, and a pulse envelope 206 of the valve electric field incident with a probe electric field on a region 820 of an insulator 802, so as to coherently control a response of the region of the insulator to the probe electric field 812 such that the response is controlled with a temporal resolution equal to the pulse length and matching the pulse envelope.
28. A method of operating an optical valve, comprising:
   at least providing, selecting, or controlling a timing of a valve electric field 806, a pulse length 204 of the valve electric field, a magnitude or amplitude 205 of the valve electric field, and a pulse envelope 206 of the valve electric field incident with a probe electric field on an insulator, so as to coherently control a response of the insulator to the probe electric field 812 such that the response is controlled with a temporal resolution equal to the pulse length and matching the pulse envelope, wherein:
   the insulator comprises:
   a first state and a second state separated in energy by a bandgap and coupled by a first dipole allowed transition; and
   a nonlinear susceptibility associated with the first the dipole allowed transition; and
   the valve electric field comprises:
   a first frequency corresponding to a photon energy smaller than the bandgap and any in gap energy corresponding to a second dipole allowed transition within the bandgap; and
   the magnitude is selected for driving a virtual transition between the first state and the second state under Floquet conditions that increase the bandgap by an amount proportional to a square of the magnitude.
29. An optical valve, comprising:
   an insulator comprising:
   a first state and a second state separated in energy by a bandgap and coupled by a first dipole allowed transition; and
   a nonlinear susceptibility associated with the first dipole allowed transition;
   a source of a valving electric field coupled to a region of the insulator, the valving electric field comprising:
   a first frequency corresponding to a photon energy smaller than the bandgap and any in gap energy corresponding to a second dipole allowed transition within the bandgap; and
   a magnitude selected for driving a virtual transition between the first state and the second state under Floquet conditions that increase the bandgap by an amount proportional to a square of the magnitude; and
   a computer and/or control circuit 810 controlling a timing of the valve electric field 806, a pulse length 204 of the valve electric field, the magnitude 205 (e.g. amplitude), and a pulse envelope 206 of the valve electric field so as to coherently control a response of the region of the insulator to a probe electric field, the response controlled with a temporal resolution equal to the pulse length and matching the pulse envelope.
30 A system, device, or method of any of the examples 1-26 utilizing or comprising the circuit, method or valve of any of the examples 27-29.

### Advantages and Improvements

The ability to widely tune the optical nonlinearity of a material with ultrafast speed is crucial for advancing photonics technologies spanning optical signal processing, on-chip nonlinear optical sources and optical computing. However, the nonlinear optical properties of materials, dictated by their electronic and crystallographic structures, are largely set at the synthesis and fabrication stages. Further in situ tuning may be achieved by changing the temperature, pressure ¹⁵, electric field ¹⁶, current density^{17,18} or carrier concentration ^{19,20}, but these approaches are static and often materials specific. Dynamical tuning based on light-induced phase transitions ^{21,22} or photocarrier density modulation ²³ have been demonstrated. However, these approaches impart significant heating and are limited in speed owing to electronic and structural relaxation bottlenecks.

Unlike heat based optical valves, the mechanism described herein is completely coherent (i.e., heat free). This means that the duration of this bandgap change is determined by the duration of the light pulse, not requiring any waiting time for trapped heat to dissipate. It also means less wear and tear on the material with repeated use. Embodiments disclosed herein demonstrate that the optical valve can be switched on/off on a time scale faster than 100 femtoseconds, but this is not a fundamental limit (we were limited by the available instrumentation in our laboratory). The magnitude of the pump induced bandgap change depends on the intensity and polarization of the pump light. Moreover, this scheme can in principle to applied to any insulating material. Therefore, optical valves can be made compatible with a wide range of wavelengths using this approach, by choosing a material with the appropriate bandgap and tuning the intensity or polarization of the pump light. Currently, intense optical pumping fields need to be used, but this can be achieved in one or more embodiments using a commercial high power ultrafast laser.

### References

The following references are incorporated by reference herein
1 Oka, T. & Aoki, H. Photovoltaic Hall effect in graphene. Phys. Rev. B 79, 081406 (2009).
2 Kitagawa, T., Oka, T., Brataas, A., Fu, L. & Demler, E. Transport properties of nonequilibrium systems under the application of light: photoinduced quantum Hall insulators without Landau levels. Phys. Rev. B 84, 235108 (2011).
3 Rudner, M. S. & Lindner, N. H. Band structure engineering and nonequilibrium dynamics in Floquet topological insulators. Nat. Rev. Phys. 2, 229-244 (2020).
4 Hübener, H., Sentef, M. A., De Giovannini, U., Kemper, A. F. & Rubio, A. Creating stable Floquet-Weyl semimetals by laser-driving of 3D Dirac materials. Nat. Commun. 8, 13940 (2017).
5 Mclver, J. . et al. Light-induced anomalous Hall effect in graphene. Nat. Phys. 16, 38-41 (2020).
6 Wang, Y. H., Steinberg, H., Jarillo-Herrero, P. & Gedik, N. Observation of Floquet-Bloch states on the surface of a topological insulator. Science 342, 453-457 (2013).
7 Mentink, J. H., Balzer, K. & Eckstein. M. Ultrafast and reversible control of the exchange interaction in Mott insulators. Nat. Commun. 6, 6708 (2015).
8 Claassen, M., Jiang, H. C., Moritz, B. & Devereaux, T. P. Dynamical time-reversal symmetry breaking and photo-induced chiral spin liquids in frustrated Mott insulators. Nat. Commun. 8, 1192 (2017).
9 Liu, J., Hejazi, K. & Balents, L. Floquet engineering of multiorbital Mott insulators: applications to orthorhombic titanates. Phys. Rev. Lett. 121, 107201 (2018).
10 Mikhaylovskiy, R. V. et al. Ultrafast optical modification of exchange interactions in iron oxides. Nat. Commun. 6, 8190 (2015).
11 Chaudhary, S., Hsieh, D. & Refael, G. Orbital Floquet engineering of exchange interactions in magnetic materials. Phys. Rev. B 100, 220403 (2019).
12 Mitrano, M. et al. Possible light-induced superconductivity in K₃C₆₀ at high temperature. Nature 530, 461-464 (2016).
13 Gu, B. & Franco, I. Optical absorption properties of laser-driven matter. Phys. Rev. A 98, 063412(2018)
14 Shirley, J. H. Solution of the Schrödinger equation with a Hamiltonian periodic in time. Phys. Rev. 138, B979-B987 (1965).
15 Bayarjargal, L. & Winkler, B. Pressure-induced magnetic phase transition in Cr₂O₃ determined by second harmonic generation measurements. Appl. Phys. Lett. 102, 182403 (2013).
16 Terhune, R. W., Maker, P. D. & Savage, C. M. Optical harmonic generation in calcite. Phys. Rev. Lett. 8, 404-406 (1962).
17 An, Y. Q., Nelson, F., Lee, J. U. & Diebold, A. C. Enhanced optical second-harmonic generation from the current-biased graphene/ Si0_{2/}Si(001) structure. Nano Lett. 13 2104-2109 (2013).
18 Ruzicka, B. A. et al. Second-harmonic generation induced by electric currents in GaAs. Phys. Rev. Lett. 108, 077403 (2012).
19 Seyler, K. L. et al. Electrical control of second-harmonic generation in a WSe₂ monolayer transistor. Nat. Nanotechnol. 10, 407-411 (2015).
20 Soavi, G. et al. Broad-band, electrically tunable third-harmonic generation in graphene. Nat. Nanotechnol. 13, 583-588 (2018).
21 Satoh, T., Van Aken, B. B., Duong, N. P., Lottermoser, T. & Fiebig, M. Ultrafast spin and lattice dynamics in antiferromagnetic Cr₂O₃. Phys. Rev. B 75,155406 (2007).
22 Zhang, M. Y. et al. Light-induced subpicosecond lattice symmetry switch in MoTe₂. Phys. Rev. X 9, 021036 (2019).
23 Sartorello, G. et al. Ultrafast optical modulation of second- and thirdharmonic generation from cut-disk-based metasurfaces. ACS Photon. 3, 1517-1522 (2016).
24 Piryatinskaya, V. G., Kachur, I. S., Slavin, V. V., Yeremenko, A. V. & Vysochanskii, Y. M. Temperature behavior of the fundamental optical absorption band in quasi-two-dimensional crystalline MnPS₃. Low Temp. Phys. 38, 870-873 (2012).
25 Chu, H. et al. Linear magnetoelectric phase in ultrathin MnPS₃ probed by optical second harmonic generation. Phys. Rev. Lett. 124, 027601 (2020).
26 Vaclavkova, D. et al. Magnetoelastic interaction in the two-dimensional magnetic material MnPS₃ studied by first principles calculations and Raman experiments. 2D Mater. 7, 035030 (2020)
27 Kurosawa, K., Saito, S. & Yamaguchi, Y. Neutron diffraction study on MnPS₃ and FePS₃. J. Phys. Soc. Jpn 52, 3919-3926 (1983).
28 Grasso, V., Neri, F., Perillo, P., Silipigni, L. & Piacentini, M. Optical-absorption spectra of crystal-field transitions in MnPS₃ at low temperatures. Phys. Rev. B 44, 11060-11066 (1991).
29 Fiebig, M., PavlovV. V. & Pisarev, R. V. Second-harmonic generation as a tool for studying electronic and magnetic structures of crystals: review. J. Opt. Soc. Am. B 22,96-118 (2005)
30 Boyd, R. W. Nonlinear Optics (Academic Press, 2003).
31 Muthukumar, V. N., Valenti, R. & Gros, C. Microscopic model of nonreciprocal optical effects in Cr₂O₃. Phys. Rev. Lett. 75, 2766-2769 (1995).
32 Harter, J. W., Niu, L., Woss, A. J. & Hsieh, D. High-speed measurement of rotational anisotropy nonlinear optical harmonic generation using position-sensitive detection. Opt. Lett. 40, 4671-4674 (2015).
33 Wildes, A. R., Rønnow, H. M., Roessli, B., Harris, M. J. & Godfrey, K. W. Static and dynamic critical properties of the quasi-two-dimensional antiferromagnet MnPS₃. Phys. Rev. B 74, 094422 (2006).
34 Autler, S. H. & Townes, C. H. Stark effect in rapidly varying fields. Phys. Rev. 100, 703-722 (1955).
35 Sie, E. J. et al. Valley-selective optical Stark effect in monolayer WS₂. Nat. Mater. 14 290-294 (2015).
36 Bloch, F. & Siegert, A. Magnetic resonance for nonrotating fields. Phys. Rev. 57, 522-527 (1940).
37 Sentef, M. A., Li, J., Künzel, F. & Eckstein, M. Quantum to classical crossover of Floquet engineering in correlated quantum systems. Phys. Rev. Res. 2, 033033 (2020).
38 Further information on one or more embodiments of the present invention can be found in “Giant modulation of optical nonlinearity by Floquet engineering”, by Jun-Yi Shan et. al., Nature, Vol 600, Dec. 9, 2021, https://doi.org/10.1038/s41586-021-04051-8.

### Conclusion

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

1. An optical valve, comprising:
an insulator comprising:
a first state and a second state separated in energy by a bandgap and coupled by a first dipole allowed transition; and
a nonlinear susceptibility associated with the first dipole allowed transition;
a source of a valving electric field coupled to a region of the insulator, the valving electric field comprising:
a first frequency corresponding to a photon energy smaller than the bandgap and any in gap energy corresponding to a second dipole allowed transition within the bandgap; and
a magnitude selected for driving a virtual transition between the first state and the second state under Floquet conditions that increase the bandgap by an amount proportional to a square of the magnitude; and
a control circuit controlling a timing of the valve electric field, a pulse length of the valve electric field, the magnitude, and a pulse envelope of the valve electric field so as to coherently control a response of the region of the insulator to a probe electric field, the response controlled with a temporal resolution equal to the pulse length and matching the pulse envelope.

2. The optical valve of claim 1, wherein the magnitude dresses the states with Floquet sidebands characterized by the first state and the second state gaining a mixing factor cosα wherein α is proportional to the magnitude.

3. The optical valve of claim 1, wherein the probe electric field has a second frequency tuned for absorption by the bandgap prior to application of the valve electric field and the control circuit controls a transparency of the region of insulator for the probe electric field by modulating the bandgap.

4. The optical valve of claim 1, wherein the control circuit controls a nonlinear response of the region of the insulator to the probe electric field, wherein the nonlinear response is mediated by the nonlinear susceptibility being switched on or off by the valve electric field.

5. The optical valve of claim 4, wherein the probe electric field has a second frequency and the control circuit controls a detuning of the second frequency to either side of the first dipole allowed transition so as to enhance or suppress the nonlinear response.

6. An optical rectifier or high harmonic generator comprising the optical valve of claim 1, wherein the control circuit controls optical rectification or generation of higher harmonics of the probe electric field via the valve electric field.

7. A cavity comprising the insulator of claim 1, wherein the cavity reduces the magnitude of the valve electric field required to modify the transparency for the electromagnetic radiation comprising the second electric field.

8. An optical transistor comprising the optical valve of claim 1, wherein the valve electric field modulates an optical response of the region to the probe electric field.

9. The optical valve of claim 1, wherein the insulator comprises a two-dimensional van der Waals layered magnetic insulator or a 2D exfoliable material.

10. The optical valve of claim 9, wherein the first state is a spin state comprising A_{1g} symmetry and the second state has charge transfer character.

11. The optical valve of claim 1, wherein the insulator comprises ions disposed in two dimensional layers of a honeycomb lattice.

12. The optical valve of claim 11, wherein the ions each have spin magnetic moment moments adopting a Neel antiferromagnetic (AFM) arrangement that breaks the inversion symmetry of the honeycomb lattice, allowing a second-order optical nonlinearity of the first dipole allowed transition.

13. The optical valve of claim 1, wherein the insulator comprises a magnetic insulator comprising manganese phosphorus trisulfide.

14. The optical valve of claim 1, wherein the pulse length is 500 femtoseconds or less.

15. A device, comprising:
a control circuit for controlling a timing of a valve electric field, a pulse length of the valve electric field, a magnitude, and a pulse envelope of the valve electric field incident with a probe electric field on a region of an insulator, so as to coherently control a response of the region of the insulator to the probe electric field such that the response is controlled with a temporal resolution equal to the pulse length and matching the pulse envelope.

16. The device of claim 15, wherein the control circuit controls the magnitude so as to dress a first state and a second state of the insulator with Floquet sidebands characterized by the first state and the second state gaining a mixing factor cosα wherein α is proportional to the magnitude.

17. The device of claim 15, wherein the control circuit controls a transparency of the region of insulator for the probe electric field by modulating a bandgap of the insulator.

18. The device of claim 15, wherein the control circuit controls a nonlinear response of the region of the insulator to the probe electric field by gating or switching the valve electric field on or off.

19. The device of claim 15, wherein the control circuit controls a detuning of a second frequency of the probe electric field to either side of the first dipole allowed transition between the first state and the second state so as to enhance or suppress a nonlinear response of the insulator to the probe electric field.

20. (canceled)

21. A method of operating an optical valve, comprising:
at least providing, selecting, or controlling a timing of a valve electric field, a pulse length of a valve electric field, a magnitude of the valve electric field, and a pulse envelope of the valve electric field incident with a probe electric field on an insulator, so as to coherently control a response of the insulator to the probe electric field such that the response is controlled with a temporal resolution equal to the pulse length and matching the pulse envelope, wherein:
the insulator comprises:
a first state and a second state separated in energy by a bandgap and coupled by a first dipole allowed transition; and
a nonlinear susceptibility associated with the first the dipole allowed transition; and
the valve electric field comprises:
a first frequency corresponding to a photon energy smaller than the bandgap and any in gap energy corresponding to a second dipole allowed transition within the bandgap; and
the magnitude is selected for driving a virtual transition between the first state and the second state under Floquet conditions that increase the bandgap by an amount proportional to a square of the magnitude.
